(19) United States
(12) Patent Application Publication
(10) Pub. No.: US 2011/0139728 A1
(43) Pub. Date: Jun. 16, 2011

(54) Device and Process for Substance Separation in a Microstructured Apparatus

(75) Inventors: Jürgen Kern, Geisenheim (DE); Thomas Runowski, Hilden (DE); Marcus Paul Grün, Leverkusen (DE); Gerhard Ruffert, Leverkusen (DE); Rebeka Zecirovic, Köln (DE); Jörg-Rainer Schmitz, Ratingen (DE); Helmut Mothes, Langenfeld (DE); Olaf Stange, Singapore (SG); Frank Herbstritt, Alzey (DE)

(73) Assignees: BAYER TECHNOLOGY SERVICES GMBH, Leverkusen (DE); EHRFELD MIKROTECHNIK BTS GMBH, Wendelsheim (DE)

(21) Appl. No.: 13/058,500

(22) PCT Filed: Aug. 5, 2009
(86) PCT No.: PCT/EP2009/005650

§ 371 Date: Feb. 10, 2011

(30) Foreign Application Priority Data
Aug. 15, 2008 (DE) 10 2008 037 901.8

(51) Int. Cl. B01D 17/02; B01J 19/00; B81B 1/00

(52) U.S. Cl. 210/749; 210/198.1; 210/177; 210/799

(57) ABSTRACT

The invention relates to a device for separation of substance mixtures on the micro scale. The invention further relates to a process for separating substance mixtures using the inventive device. The device is a device for separating substance mixtures and for performing chemical reactions between immiscible fluid media on the micro scale, comprising a first channel plate with at least one first process channel for a first fluid medium, an inlet and an outlet, and a connecting or distributing channel in each case, which connects the inlet to the first process channel, and a further connecting or distributing channel which connects the first process channel to the outlet, a second channel plate with at least one second process channel for a second fluid medium immiscible with the first, an inlet and an outlet, and a connecting or distributing channel in each case, which connects the inlet to the second process channel, and a further connecting or distributing channel which connects the second process channel to the outlet, and a microscreen as a separating means between the two process channel, wherein the microscreen has a multitude of orifices which have an aspect ratio of 1.5 to 10.

This is an application filed under 35 USC §371 of PCT/EP2009/005650 filed on Aug. 5, 2009 and claiming priority to DE 10 2008 037 901.8 filed on Aug. 15, 2008.

### BACKGROUND OF THE INVENTION

(1) Field of the Invention

The invention relates to a device for separating substance mixtures and also for carrying out chemical reactions between immiscible fluid media in microstructured channels. The invention further relates to a process for separating substance mixtures and for carrying out chemical reactions between immiscible fluid media using the device according to the invention “Immiscible fluid media” are taken to mean those liquid or gaseous media which form a phase boundary among one another under the given conditions. In addition, the device is suitable for degassing and gassing individual substance streams and mixtures and also for generating emulsions, in particular microemulsions and nanoemulsions.

The separation of substance mixtures by mass transfer between fluid media, e.g. by means of distillation, absorption, desorption and extraction is a long-known technique that is carried out not only on a small scale but also on an industrial scale. Likewise, devices and processes are known for carrying out chemical reactions between substances that are present in different fluid phases, for instance e.g. between gases and liquids, and also between mutually immiscible liquids.

(2) Description of Related Art

For some time it has been known that a procedure for separating substance mixtures or for chemical reactions between immiscible fluid media in microstructured channel systems and using separation means microstructured in a defined manner has advantages with respect to hydrodynamics and also heat and mass transport compared with the use of conventional columns (see, for example, Cypes, Engstrom, Chemical Engineering Journal 101 (2004) 49). Separation means that come into consideration here are the channel walls themselves and also films or membranes having in each case microstructured openings introduced in a defined manner between the channels for the fluids that are to be brought into contact. A defined aspect ratio of the openings of the separation means used is, however, not disclosed in the abovementioned publication.

WO 96/12540 discloses a device which has a perforated plate means of the membrane type and is suitable, inter alia, for separating substance mixtures in microstructured channels. With respect to the embodiment of the openings (pores) in the perforated plate means, WO 96/12540 teaches that an aspect ratio, i.e. the ratio between the smallest lateral dimension of the openings to the thickness of the perforated plate means of not greater than 1 is necessary in order to achieve a satisfactory separation efficiency.

It has however been found that using these known devices for separating substance mixtures and also for carrying out chemical reactions between immiscible fluid media on a microscale, for many applications, processing of only insufficient mass streams based on the area of the separation means is possible. This prevents use of these devices in those applications in which process-specific high mass streams must be managed. Examples of industrial processes of this type are the dechlorination of HCl or the drying of chlorine using sulfuric acid. This disadvantage may at best be compensated for by parallel operation of a multiplicity of these known devices, which, however, in turn leads to high capital and operating costs.

### BRIEF SUMMARY OF THE INVENTION

The object was therefore to provide a device for separating substance mixtures and also for carrying out chemical reactions between immiscible fluid media in microstructured channels, which is able to manage a high mass stream based on the area of the separation means with, as far as possible, unchanged good separation efficiency. The device should in addition be simple in construction and be inexpensive to produce.

Surprisingly, it has now been found that these objects are solved by the device according to the invention described hereinafter.

The present invention therefore relates to a device for separating substance mixtures and also for carrying out chemical reactions between immiscible fluid media in microstructured channels comprising a first channel plate having at least one first process channel for a first fluid medium, an inlet and an outlet and also a connecting channel or distributing channel in each case that connects the inlet to the first process channel and having a further connecting channel or distributing channel that connects the first process channel to the outlet, a second channel plate having at least one second process channel for a second fluid medium that is immiscible with the first fluid medium, an inlet and an outlet and also a connecting channel or distributing channel in each case that connects the inlet to the second process channel and having a further connecting channel or distributing channel that connects the second process channel to the outlet, and also a microscreen as separation means between the two process channels, wherein the microscreen contains a multiplicity of openings that have an aspect ratio of 1.5 to 10, preferably 1.5 to 5, particularly preferably 2 to 3.

The aspect ratio in this case denotes the ratio of the smallest dimension of the opening, measured in parallel to the screen membrane surface, to the thickness of the screen membrane.

The openings of the microscreen are preferably of approximately equal size and are distributed substantially regularly on the microscreen.

The thickness of the microscreen is customarily 0.5 to 10 μm, preferably 0.5 to 5 μm, particularly preferably 0.5 to 2 μm.

The diameter of the openings is customarily 0.2 to 5 μm, preferably 0.2 to 2 μm, particularly preferably 0.2 to 1 μm.

In each case, however, the abovementioned aspect ratio must be complied with.

In order to achieve good mass transport through the microscreen, it is advantageous to use microscreens of particularly high porosity, i.e. a large total cross-sectional area of the openings (pores) per screen surface. The porosity, on the other hand, is restricted here by the requirement that the screen must have a certain strength in order to ensure reliable separation between the fluids that are to be brought into contact for the purpose of mass transfer. Microscreens having porosities between 10% and 70%, preferably between 20% and 60%, particularly preferably between 30% and 50%, have proved to be expedient.

Suitable microscreens for the device according to the invention are, for example, the microscreens having the designation DX05 marketed by the company FluXXion b.v, Einhoven, the Netherlands.

Fluid can be fed to and removed from the channels via supply channels which make possible uniform distribution of the fluids.

The fluids can be heated/cooled by heat introduction and removal externally into or out of the module.

There is in addition the possibility of stacking a plurality of microscreens with channels lying in between and connecting them in series or parallel.

In addition, in such an arrangement between each or between selected channel or screen pair(s), heating/cooling plates can be provided, wherein the heating/cooling plates make possible heat introduction or removal. The heating/cooling plates can be, for example, cooled or heated via fluid channels by a through-flowing fluid.

Further conceivable structures of the device according to the invention are what are termed coiled or capillary or tube modules. These structures are known to those skilled in the art in the field of membrane technology.

Suitable materials for the microscreen are, e.g., metals, glasses, ceramics, polymer materials or semiconductors. Preferably, semiconductor materials are used for producing the microscreens, particularly preferably silicon and silicon nitride. The use of nanomaterials such as carbon nanotubes is also possible.

The openings of the microscreen may be produced by generally known processes of microstructuring. Preferably, in this case, methods of photolithography are used in combination with coating and etching techniques, such as are known, e.g., from the fabrication of microelectronic and microsystem construction elements. Particularly preferably the coating techniques are vacuum-aided methods for depositing thin layers of particularly chemically and mechanically stable compounds (e.g. silicon nitride) and the etching processes are wet-chemical or vacuum-aided processes for isotropic and also anisotropic material erosion in semiconductor materials. Laser processes, deposition techniques or machining production processes can also be used.

For certain applications it can be advantageous to coat the microscreen. For this purpose, generally known materials and techniques come into consideration. By means of a coating it is possible, in particular, to set the surface properties of the microscreen. Thus, for example, a coating can be applied which is wettable or not wettable with respect to the respective liquid phase that is to be separated. In order to effect reliable separation of the fluids that are to be brought into contact via the microscreen, it is preferred in each case to set the contact angle between the surface of the coated microscreen and the liquid phase(s) to a value that is as far removed from 90° as possible. If the device is used for bringing a liquid having a high surface tension (e.g. water) into contact with a gas, it is particularly advantageous to establish the surface of the screen to be water-repellent (hydrophobic: interface angle of the water versus the screen surface >>90°. Vice versa, when the device is used for mass transfer between a liquid having a low surface tension (e.g. toluene) and a gas, it can be particularly advantageous to establish the screen to be readily wetting with respect to the liquid (interface angle of the liquid versus the screen surface <<90°.

Suitable coating means for coating the microscreen are, for example, coating means based on silane or polytetrafluoroethylene (Teflon).

A particularly preferred coating means when aqueous liquid phases are used is polytetrafluoroethylene (Teflon).

In addition to setting the wettability by the process media, it can likewise be advantageous to coat the microscreen with a catalytically active substance.

In order, in the region of the process channels, to achieve sufficient mass transport within the participating fluids also, and thereby prevent accumulation or depletion of the species to be transported inhibiting the mass transport through the microscreen, it is, in particular in the case of liquid media, advantageous that the process channel has, in the direction perpendicular to the screen surface, a low extension (depth). Preferably, therefore, at least on the side of the liquid process medium, process channel depths of 5 to 50 μm, particularly preferably 10 to 30 μm, should be used. Owing to the preferably very small dimensions of the screen openings and the aspect ratios thereof lying significantly over 1, even in the case of such small channel depths and high process media fluxes, the resultant high differential pressures over the microscreen in the countercurrent flow operation of the device may be safely managed.

The introduction of the process channels having the abovementioned channel depths into the channel plates can proceed with sufficient precision using methods of microfabrication known from microproduction technology such as, e.g., by etching processes, machining techniques or laser material cutting (ablation). Alternatively, and preferred to the abovementioned methods, the channel plates can be made planar on the side of the liquid process channels and the process channels can be defined by introducing between the channel plate and the microscreen a film that is structured in the form of continuous openings. The thickness of the film corresponds in this case to the process channel depth.

The connecting or distributing channels are preferably to be made in such a manner that a homogeneous distribution of the fluid streams in the process channels is ensured. For the majority of the possible applications of the device it is advantageous that the mutually immiscible fluids flow through the process channels that are separated by the microscreen in directions that are substantially parallel to one another. It is particularly advantageous when the two fluids in the process channels separated by the microscreen flow in opposite direction to one another.

Depending on the application of the device, it can be advantageous to fit it with means for introducing or removing heat. Thus, for example, further channels separated from the process channels and connecting/distributing channels can be introduced into the channel plates which make possible flow of a heating/cooling medium through the channel plates or additional channel plates solely provided with heating/cooling channels can be built into the device. Alternatively, e.g., heating by electrically driven resistance heating elements, by microwave irradiation or irradiation of other electromagnetic waves or cooling using Peltier elements is also possible.

It can in addition be advantageous to equip the device with means for introducing light (e.g. IR, visible light or UV radiation) into the process channels in order to cause, for example, photochemical reactions between the process media or substances dissolved therein. For example, semiconductor light sources, preferably light-emitting diodes having a narrow emission spectrum, can be built directly into the channel plates, or the radiation from external light sources (e.g. light-emitting or laser diodes, gas discharge lamps, solid or gas lasers etc.) can be passed into the device and there into the region of the process channels via suitable coupling devices such as lenses, mirrors, gratings and/or light conductors.

The present invention likewise relates to an apparatus that comprises more than one device according to the invention that are mutually connected (“interconnected”). Such an interconnection can be, in particular, in parallel or series, which enables a multistage substance separation to be carried out.

In a particular embodiment, the interconnection makes possible the operation of the individual devices of the apparatus under different conditions with respect to temperature and/or pressure.

In a further particular embodiment, the interconnection, for example by the inward transfer and/or ejection of substance streams, makes possible the operation of the individual devices of the apparatus at different concentrations of the substances flowing through the apparatus.

The device according to the invention can be used advantageously for separating a great number of substance systems. Some systems, which will only be mentioned by way of example, are chlorobenzene/ethylbenzene or toluene/water/nitrogen. The device according to the invention can be used in this case not only in absorption processes but also in distillation processes.

In addition, the device can advantageously be used for carrying out chemical reactions between immiscible fluids, in particular between gases and liquids. In this case, owing to the low depth of the process channels, the possibility is offered of removing very rapidly and efficiently the heat of reaction formed at the interface between the two reaction media. It is possible thereby, for example, to carry out strongly exothermic gas-liquid reactions such as, e.g., direct halogenations, phosgenations or ozonizations of organic media at high concentration of the reaction media and in a very short time under controlled temperature and residence time conditions. In addition, chemical reactions can be accelerated or first made possible at all between the reaction media or individual components thereof by catalytically active substances applied to the microscreen or to the inner surfaces of one of the process channels.

The device according to the invention makes possible, at comparably high mass transport capacity to that of known microstructured devices for separating fluid media or for carrying out chemical reactions between immiscible fluid media, on the basis of the area of the separation means (microscreen), the processing of a significantly higher mass stream, which makes it possible to succeed with fewer or smaller devices. The device according to the invention is, in addition, simple and cheap to produce and operate.

The present invention further relates to a process for separating a liquid substance mixture which is characterized by the use of at least one device according to the invention.

The invention will be illustrated by the examples hereinafter, without being restricted to these examples however.

### EXAMPLES

The desorption of toluene was studied from a toluene/water mixture with nitrogen. The type of mass transport and the substance system were selected in order to be able to compare the results with those of Cypes and Engstrom, Chemical Engineering Journal 101 (2004) 49, who carried out similar measurements for the “microfabricated stripping column” developed by them and compared these with the results of a conventional column.

### BRIEF DESCRIPTION OF THE SEVERAL VIEWS OF THE DRAWING(S)

FIG. 1 shows a set-up for conducting an experiment.

FIG. 2 shows a comparison of the measured mass transport capacity of the “μSorb module”.

### DETAILED DESCRIPTION OF THE INVENTION

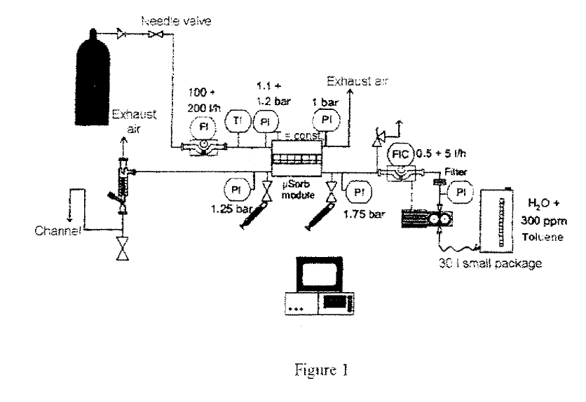

FIG. 1 shows the experimental set-up.

### DETAILED DESCRIPTION OF THE INVENTION

FIG. 1 shows the experimental set-up. The device according to the invention is designated “μSorb module”. For illustration, image 1 also shows typical state and process parameters. For determining the mass transport, samples were taken on the liquid side at inlet and outlet of the module, the composition of which samples was determined chromatographically. From the measured change in liquid concentration, the overall mass-transfer coefficient was determined.
For evaluating the mass transport capacity, the results were compared with literature data.

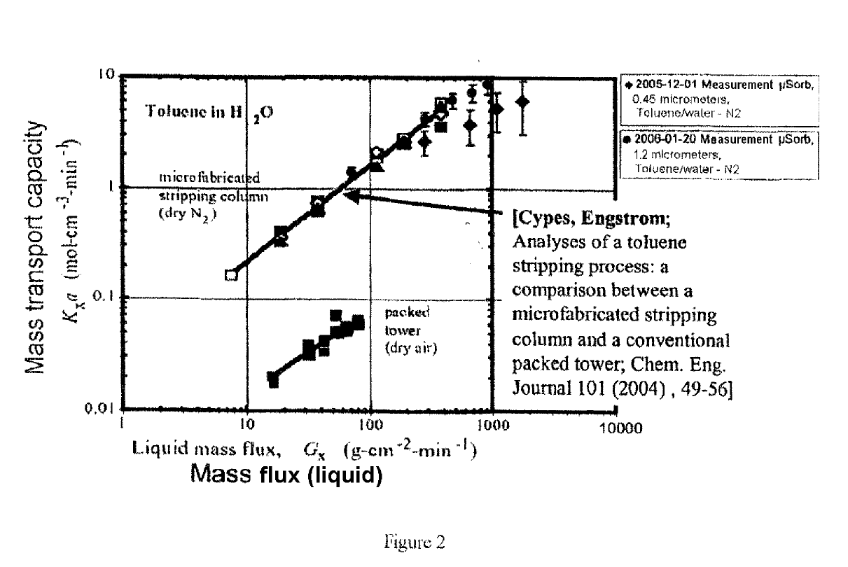

FIG. 2 shows the comparison of the measured mass transport capacity of the “μSorb module” with literature data, wherein the error bars take into account the error in measurement of the analysis.

The measured values of the device according to the invention show a mass transport capacity about two orders of magnitude greater than that of a packed column.

Compared with the “microfabricated stripping column” (MFSC), in addition, significantly higher mass streams could be realized.

Experimental data with screen holes of diameter 1.2 μm and 0.45 μm were plotted. The active screen has a thickness of 0.8 μm, i.e. for the screen having hole diameter 1.2 μm, the aspect ratio is about 0.7 (not according to the invention) and for the screen having hole diameter 0.45 μm, the aspect ratio is 1.8 (according to the invention). Surprisingly, it is shown that at an aspect ratio of 1.8, significantly higher throughput rates could be achieved than with the screen having the lower aspect ratio of the openings.

1. A device for separating substance mixtures and for carrying out chemical reactions between immiscible fluid media on the microscale comprising a first channel plate having at least one first process channel for a first fluid medium,
an inlet and an outlet and a connecting channel or distributing channel that connects the inlet to the at least first process channel and having a further connecting channel or distributing channel that connects the first process channel to the outlet,
a second channel plate having at least one second process channel for a second fluid medium that is immiscible with the first fluid medium, an inlet and an outlet and also a connecting channel or distributing channel that connects the inlet to the second process channel and having a further connecting channel or distributing channel that connects the second process channel to the outlet, and a microscreen as separation means between the two process channels, wherein the microscreen contains a plurality of openings that have an aspect ratio of 1.5 to 10.

2. The device as claimed in claim 1, wherein the openings of the microscreen are of approximately equal size and are distributed substantially regularly on the microscreen.

3. The device as claimed in claim 1, wherein the openings have a diameter of the microscreen is 0.2 to 5 μm.

4. The device as claimed in claim 2, wherein the microscreen has thickness of 0.5 to 10 μm.

5. The device as claimed in claim 2, wherein the porosity of the microscreen is between 10% and 70%.

6. The device as claimed in claim 2, wherein the microscreen has a coated surface.

7. The device as claimed in claim 1, wherein the process channels for at least one of the two fluids are formed by openings in a spacer film that is introduced between the microscreen and the respective channel plate.

8. The device as claimed in claim 1, wherein the device is additionally fitted with means for introducing or discharging heat.

9. An apparatus comprising at least two devices as claimed in claim 1, wherein the devices are interconnected with one another.

10. A method for using the device as claimed in claim 1, for carrying out chemical reactions between immiscible fluids or for separating two fluids, the method comprising
providing a first channel plate having at least one first process channel for a first fluid medium,
providing an inlet and an outlet and a connecting channel or distributing channel that connects an inlet to the at least first process channel and having a further connecting channel or distributing channel that connects the first process channel to the outlet,
a second channel plate having at least one second process channel for a second fluid medium that is immiscible with the first fluid medium, an inlet and an outlet and also a connecting channel or distributing channel that connects the inlet to the second process channel and having a further connecting channel or distributing channel that connects the second process channel to the outlet, and a microscreen as separation means between the two process channels, wherein the microscreen contains a plurality of openings that have an aspect ratio of 1.5 to 10.
